(19) United States
(12) Patent Application Publication
(10) Pub. No.: US 2024/0413181 A1
(43) Pub. Date: Dec. 12, 2024

(54) LIGHT DEFLECTING DEVICE AND DISTANCE MEASURING DEVICE

(71) Applicant: SONY SEMICONDUCTOR SOLUTIONS CORPORATION, KANAGAWA (JP)

(72) Inventors: TOSHIFUMI YASUI, TOKYO (JP); KOUHEI ANJU, TOKYO (JP); YOHTARO YASU, KANAGAWA (JP); YOSHIKI EBIKO, KANAGAWA (JP)

(21) Appl. No.: 18/699,022

(22) PCT Filed: Aug. 30, 2022
(86) PCT No.: PCT/JP2022/032492

§ 371 Date: Apr. 5, 2024

(30) Foreign Application Priority Data
Oct. 13, 2021 (JP) 2021-168091

(51) Int. Cl. H01L 27/146; G01S 7/481; H01L 23/00

(52) U.S. Cl. CPC H01L 27/14625; G01S 7/4817; H01L 24/08; H01L 27/14627; H01L 27/14634; H01L 27/14636; H01L 2224/08145

(57) ABSTRACT

A light deflecting device and a distance measuring device in which spread of emission light is suppressed and an effective opening for light reception is enlarged are provided.

A light deflecting device including a plurality of waveguides that extends in a first direction in parallel to each other and is provided in a semiconductor layer, and is capable of emitting light to an external space of the semiconductor layer and receiving light from the external space, and an optical system that is provided on a substrate including the semiconductor layer and converts light deflected and emitted from the plurality of waveguides in the first direction into a light beam substantially parallel to a second direction orthogonal to the first direction.

### TECHNICAL FIELD

The present disclosure relates to a light deflecting device and a distance measuring device.

### BACKGROUND ART

As a technique for acquiring a distance to a surrounding object, a light detection and ranging (LiDAR) device is known.

The LiDAR device irradiates an object with a light beam and detects reflected light of the irradiated light beam, so that the distance to the object can be calculated from a time difference or a frequency difference between the irradiated light beam and the reflected light. Furthermore, the LiDAR device can acquire distance information of a wide visual field by two-dimensionally scanning an object with a light beam.

For example, Patent Document 1 below discloses a scanning method of a LiDAR device for the purpose of measuring a distance of a target spatial resolution in a shorter time.

### CITATION LIST

### Patent Document

Patent Document 1: Japanese Patent No. 6811862

### SUMMARY OF THE INVENTION

### Problems to be Solved by the Invention

In recent years, in the LiDAR device, it has been studied to irradiate an object with a light beam and receive reflected light reflected by the object using the same element. Accordingly, it is desirable to achieve both emission of a light beam having a small divergence angle and reception of reflected light at a large effective opening by the same element.

Therefore, the present disclosure proposes a novel and improved light deflecting device and distance measuring device capable of suppressing spread of emission light and enlarging an effective opening of light reception.

### Solutions to Problems

According to the present disclosure, there is provided a light deflecting device including a plurality of waveguides that extends in a first direction in parallel to each other and is provided in a semiconductor layer, and is capable of emitting light to an external space of the semiconductor layer and receiving light from the external space, and an optical system that is provided on a substrate including the semiconductor layer and converts light deflected and emitted from the plurality of waveguides in the first direction into a light beam substantially parallel to a second direction orthogonal to the first direction.

Furthermore, according to the present disclosure, there is provided a distance measuring device including a plurality of waveguides that extends in a first direction in parallel to each other and is provided in a semiconductor layer, and is capable of emitting light to an external space of the semiconductor layer and receiving light from the external space, and an optical system that is provided on a substrate including the semiconductor layer and converts light deflected and emitted from the plurality of waveguides in the first direction into a light beam substantially parallel to a second direction orthogonal to the first direction.

### BRIEF DESCRIPTION OF DRAWINGS

FIG. 1 is a block diagram schematically illustrating a configuration of a distance measuring device.

FIG. 2 is a vertical cross-sectional view illustrating a configuration example of a distance measuring device.

FIG. 3 is a perspective view illustrating a configuration example of a photonic crystal waveguide.

FIG. 4 is a perspective view illustrating a shape of a module lens according to a first shape example.

FIG. 5 is a vertical cross-sectional view illustrating a cross-sectional shape of the module lens illustrated in FIG. 4.

FIG. 6 is a vertical cross-sectional view illustrating a configuration of a diffraction grating provided on an optical antenna.

FIG. 7 is an image illustrating a spot shape of emission light emitted through the diffraction grating and the module lens illustrated in FIGS. 4 to 6.

FIG. 8 is an image illustrating a spot shape of emission light in a case where the emission light having the spot shape illustrated in FIG. 7 is further condensed in a 8 direction.

FIG. 9 is an image illustrating a spot shape of emission light in a case where the emission light having the spot shape illustrated in FIG. 7 is further condensed in the 8 direction.

FIG. 10 is a perspective view illustrating a shape of a module lens according to a second shape example.

FIG. 11 is a perspective view illustrating a shape of a module lens according to a third shape example.

FIG. 12 is a perspective view illustrating a shape of a module lens according to a fourth shape example.

FIG. 13 is a vertical cross-sectional view illustrating a cross-sectional shape of the module lens illustrated in FIG. 12.

FIG. 14 is an image illustrating a spot shape of emission light emitted through a diffraction grating and the module lens illustrated in FIGS. 12 and 13.

FIG. 15 is a perspective view illustrating a shape of a module lens according to a fifth shape example.

FIG. 16 is a vertical cross-sectional view illustrating a cross-sectional shape of the module lens illustrated in FIG. 15.

FIG. 17 is an image illustrating a spot shape of emission light emitted through a diffraction grating and the module lens illustrated in FIGS. 15 and 16.

FIG. 18 is a perspective view illustrating a shape of a module lens according to a sixth shape example.

FIG. 19 is a vertical cross-sectional view illustrating a cross-sectional shape of the module lens illustrated in FIG. 18.

FIG. 20 is an image illustrating a spot shape of emission light emitted through the module lens illustrated in FIGS. 18 and 19.

FIG. 21 is a perspective view illustrating a shape of a module lens according to a seventh shape example.

FIG. 22 is a vertical cross-sectional view illustrating a cross-sectional shape of the module lens illustrated in FIG. 21.

FIG. 23 is an image illustrating a spot shape of emission light emitted through the module lens illustrated in FIGS. 21 and 22.

FIG. 24 is a perspective view illustrating a shape of a module lens according to an eighth shape example.

FIG. 25 is a vertical cross-sectional view illustrating a cross-sectional shape of the module lens illustrated in FIG. 24.

FIG. 26 is an image illustrating a spot shape of emission light emitted through the module lens and the diffraction grating illustrated in FIGS. 24 and 25.

FIG. 27 is a vertical cross-sectional view illustrating a configuration of an on-chip lens and a module lens according to a first configuration example.

FIG. 28 is a vertical cross-sectional view illustrating a configuration of an on-chip lens and a module lens according to the first configuration example.

FIG. 29 is a vertical cross-sectional view illustrating a configuration of an on-chip lens and a module lens according to a second configuration example.

FIG. 30 is a vertical cross-sectional view illustrating a configuration of an on-chip lens and a module lens according to a third configuration example.

FIG. 31 is an explanatory diagram describing effects by the on-chip lens and the module lens according to the third configuration example.

FIG. 32 is a vertical cross-sectional view illustrating a configuration of a condenser lens and a module lens according to a fourth configuration example.

FIG. 33 is an explanatory diagram describing effects by the condenser lens and the module lens according to the fourth configuration example.

FIG. 34 is a schematic explanatory diagram illustrating a positional relationship between an on-chip lens according to a fifth configuration example and the light emitting/receiving unit.

FIG. 35 is a schematic explanatory diagram illustrating a positional relationship between an on-chip lens according to the fifth configuration example and the light emitting/receiving unit.

FIG. 36 is a schematic explanatory diagram illustrating a positional relationship between an on-chip lens according to the fifth configuration example and the light emitting/receiving unit.

### MODE FOR CARRYING OUT THE INVENTION

Hereinafter, preferred embodiments of the present disclosure will be described in detail with reference to the accompanying drawings. Note that, in the present specification and drawings, components having substantially the same functional configuration are denoted by the same reference signs, and redundant description is omitted.

Note that the description will be given in the following order.
1. Distance measuring device
1.1. Outline
1.2. Configuration
1.3. Optical antenna
2. First Embodiment
2.1. First shape example
2.2. Second shape example
2.3. Third shape example
2.4. Fourth shape example
2.5. Fifth shape example
2.6. Sixth shape example
2.7. Seventh shape example
2.8. Eighth shape example
2.9. Appendix
3. Second Embodiment
3.1. First configuration example
3.2. Second configuration example
3.3. Third configuration example
3.4. Fourth configuration example
3.5. Fifth configuration example

### 1. Distance Measuring Device

### 1.1. Overview

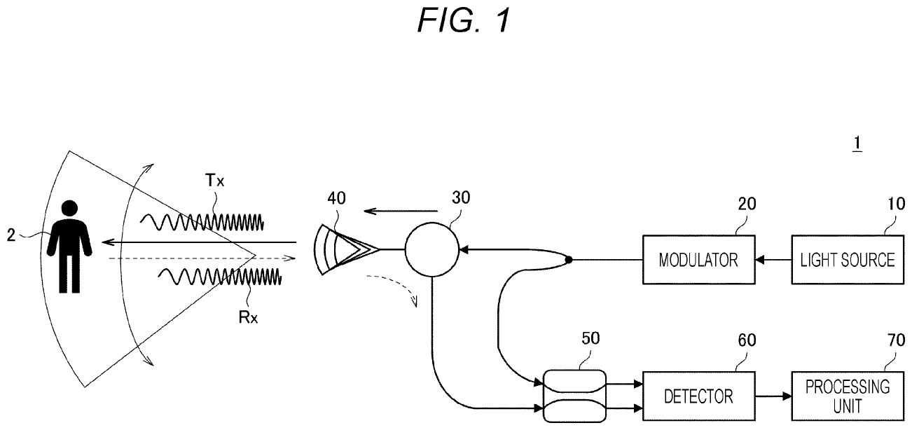

First, an outline of a distance measuring device to which the technology according to the present disclosure is applied will be described with reference to FIG. 1. FIG. 1 is a block diagram schematically illustrating a configuration of a distance measuring device 1.

As illustrated in FIG. 1, the distance measuring device 1 includes a light source 10, a modulator 20, an optical circulator 30, an optical transmission-reception unit 40, a mixer 50, a detector 60, and a processing unit 70.

The light source 10 is, for example, a laser light source that emits light belonging to a near-infrared region. The laser light emitted from the light source 10 is frequency-modulated by the modulator 20 to become frequency-chirped light whose frequency sequentially changes. The frequency-modulated frequency-chirped light is demultiplexed by a splitter or the like, and then emitted from the optical transmission-reception unit 40 to an object 2 through the optical circulator 30. Emission light Tx (Transmitter) emitted to the object 2 is reflected by the object 2 to be received by the optical transmission-reception unit 40 as reflected light Rx (Receiver). The received reflected light Rx is mixed with the frequency-chirped light demultiplexed before emission by the mixer 50 to generate a beat signal.

The reflected light Rx is delayed with respect to the emission light Tx by reciprocation between the optical transmission-reception unit 40 and the object 2. Accordingly, a frequency difference occurs between the emission light Tx and the reflected light Rx due to the frequency chirp. Thus, the mixer 50 can generate a beat signal having a frequency difference corresponding to the delay time between the emission light Tx and the reflected light Rx by mixing the received reflected light Rx and the frequency-chirped light demultiplexed before emission. The distance measuring device 1 can acquire distance information from the optical transmission-reception unit 40 to the object 2 by detecting the beat signal by the detector 60 including a photodiode or the like and performing fast Fourier transform (FFT) analysis or the like by the processing unit 70.

Furthermore, the distance measuring device 1 can two-dimensionally acquire the distance from the optical transmission-reception unit 40 to the object 2 by receiving the reflected light Rx while changing the radiation angle of the emission light Tx and two-dimensionally scanning the object 2.

### 1.2. Configuration

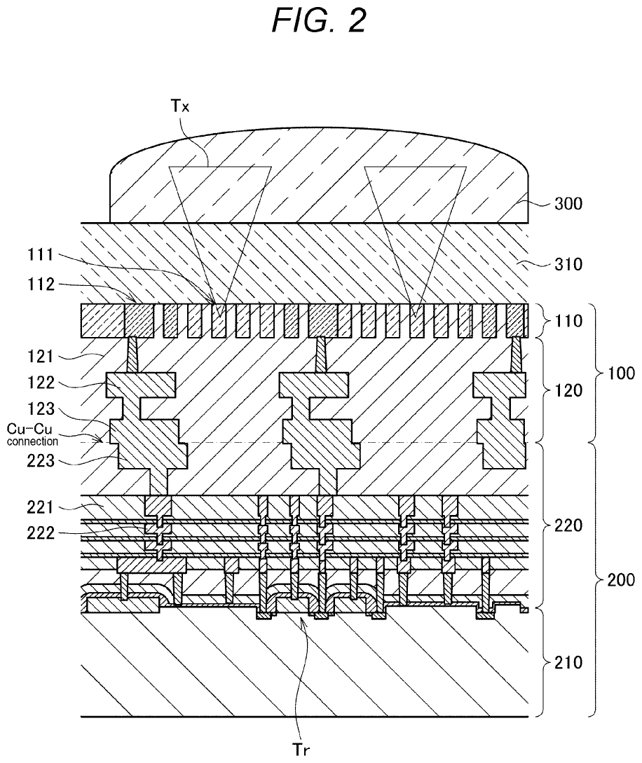

Next, a configuration example of the distance measuring device 1 will be described with reference to FIG. 2. FIG. 2 is a vertical cross-sectional view illustrating a configuration example of the distance measuring device 1.

As illustrated in FIG. 2, the distance measuring device 1 is configured using a semiconductor such as Si. For example, the distance measuring device 1 includes a first substrate 100 in which a first multilayer wiring layer 120 is stacked on a first semiconductor substrate 110, a second substrate 200 in which a second multilayer wiring layer 220 is stacked on a second semiconductor substrate 210, a planarization film 310, and a module lens 300. The first substrate 100 and the second substrate 200 are bonded together by making the first multilayer wiring layer 120 and the second multilayer wiring layer 220 face each other.

The first semiconductor substrate 110 is, for example, a Si substrate or a silicon on insulator (SOI) substrate. The first semiconductor substrate 110 is provided with an optical antenna 111 that emits the emission light Tx and a heater 112 that deflects the emission angle of the emission light Tx from the optical antenna 111.

As described later, the optical antenna 111 is a waveguide provided in a semiconductor layer in which a photonic crystal structure is formed. The optical antenna 111 functions as what is called a slow light waveguide, and can emit incident light from the waveguide toward the module lens 300 by causing laser light (for example, light belonging to a near-infrared region) emitted from a semiconductor laser not illustrated to enter the waveguide. Furthermore, the optical antenna 111 can receive light incident on the first substrate 100 through the module lens 300. That is, the optical antenna 111 corresponds to the optical transmission-reception unit 40 of FIG. 1.

For example, the heater 112 generates heat by resistance heating to heat the semiconductor layer constituting the optical antenna 111. The refractive index of the semiconductor layer constituting the optical antenna 111 changes depending on the temperature. Therefore, the heater 112 can change the deflection angle of the emission light Tx emitted from the optical antenna 111 by changing the refractive index of the semiconductor layer constituting the optical antenna 111.

The first multilayer wiring layer 120 includes a wiring layer 122, an interlayer insulating film 121, and a junction electrode 123. The wiring layer 122 includes, for example, a conductive material such as Cu, Al, Ti, or W, and electrically connects elements such as the optical antenna 111 and the heater 112 to the junction electrode 123. The interlayer insulating film 121 includes an insulating material such as SiOₓ, SiNₓ, or SiON, and electrically separates the wiring layers 122 provided in different layers. The wiring layer 122 electrically separated by the interlayer insulating film 121 is electrically connected by, for example, a via penetrating the interlayer insulating film 121.

The junction electrode 123 includes a conductive material such as Cu, for example, and is provided so as to be exposed on a bonding surface between the first multilayer wiring layer 120 and the second multilayer wiring layer 220. The junction electrode 123 can form an electrical connection between the first multilayer wiring layer 120 and the second multilayer wiring layer 220 by forming an electrode junction structure (Cu—Cu connection) in which electrodes are joined between the first multilayer wiring layer 120 and the second multilayer wiring layer 220.

The second semiconductor substrate 210 is, for example, a Si substrate or a silicon on insulator (SOI) substrate. The second semiconductor substrate 210 is provided with, for example, various transistors Tr constituting a control circuit of the emission light Tx, a control circuit of the heater 112, a processing circuit of the reflected light Rx, and the like.

The second multilayer wiring layer 220 includes a wiring layer 222, an interlayer insulating film 221, and a junction electrode 223. The wiring layer 222 includes, for example, a conductive material such as Cu, Al, Ti, or W, and electrically connects various transistors Tr formed on the second semiconductor substrate 210 and the junction electrode 223. The interlayer insulating film 221 includes SiOₓ, SiNₓ, SiON, or the like, and electrically isolates the wiring layers 222 provided in different layers from each other. Each of the wiring layers 222 electrically separated by the interlayer insulating film 221 is electrically connected by, for example, a via penetrating the interlayer insulating film 221.

The junction electrode 223 includes a conductive material such as Cu, for example, and is provided so as to be exposed on the bonding surface between the first multilayer wiring layer 120 and the second multilayer wiring layer 220. The junction electrode 223 can form an electrical connection between the first multilayer wiring layer 120 and the second multilayer wiring layer 220 by forming an electrode junction structure (Cu—Cu connection) in which electrodes are joined between the first multilayer wiring layer 120 and the second multilayer wiring layer 220.

The planarization film 310 includes a transparent material such as SiOₓ, SiNₓ, or SiON, and is provided on the first semiconductor substrate 110 of the first substrate 100. The module lens 300 includes a transparent material such as SiOₓ, SiNₓ, SiON, a glass material, or an acrylic resin, and is provided on the planarization film 310. The module lens 300 shapes the emission light Tx emitted from the optical antenna 111 into substantially parallel light beams, and condenses the reflected light Rx incident on the optical antenna 111. The module lens 300 may be provided as a convex lens.

### 1.3. Optical Antenna

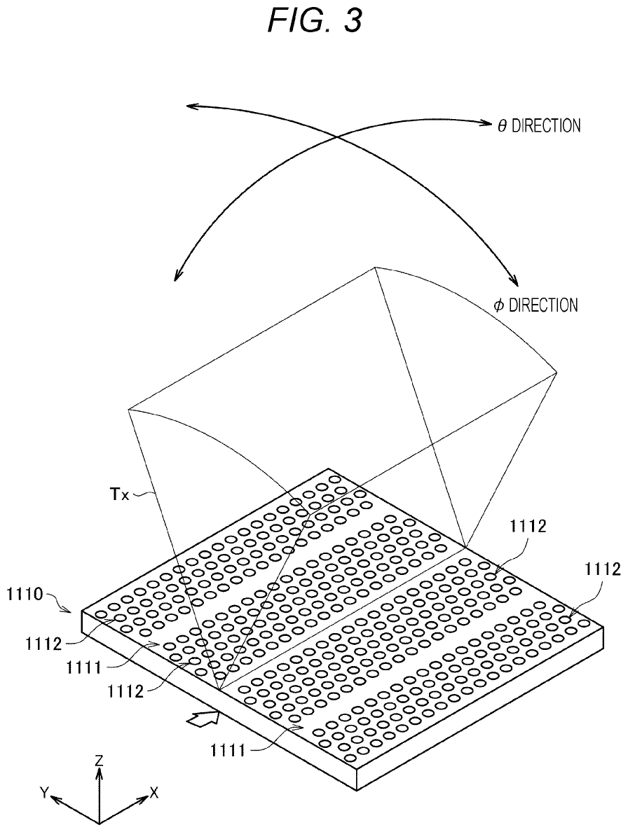

Next, a photonic crystal waveguide constituting the optical antenna 111 will be described with reference to FIG. 3. FIG. 3 is a perspective view illustrating a configuration example of a photonic crystal waveguide 1110.

As illustrated in FIG. 3, the photonic crystal waveguide 1110 includes a diffraction grating 1112 and a waveguide 1111. The diffraction grating 1112 is configured by periodically arranging a low refractive index region having a refractive index lower than that of Si between high refractive index regions including Si or the like. The waveguide 1111 has a photonic crystal structure and is provided to extend in one direction. Specifically, a plurality of waveguides 1111 is provided in parallel to each other while extending in a first direction (X-axis direction) in a region where the diffraction grating 1112 is not provided.

In the photonic crystal waveguide 1110, light incident on the waveguide 1111 is propagated in the waveguide 1111 in the first direction and is radiated above the waveguide 1111 (Z-axis direction). The light radiated to the upper side of the waveguide 1111 becomes a beam spreading in a fan shape in a second direction (Y-axis direction) orthogonal to the first direction, and is emitted while being inclined in a propagation direction of the light with respect to the Z-axis direction. The light radiated above the waveguide 1111 is shaped into a light beam substantially parallel to the second direction by an optical system such as the module lens 300. Note that the term “substantially parallel” allows a spread of about 0.01° to 0.1° from complete parallel.

In the photonic crystal waveguide 1110, by changing the refractive index of the diffraction grating 1112 depending on the temperature, the light emitted above the waveguide 1111 can be deflected in a θ direction (rotation direction around the Y axis). Furthermore, in the photonic crystal waveguide 1110, light can be deflected in a ϕ direction (rotation direction around the X axis) by switching the waveguide 1111 that emits light. According to this, the optical antenna 111 including the photonic crystal waveguide 1110 can two-dimensionally scan the emission light Tx by using deflection in the θ direction by refractive index control and deflection in the ϕ direction by switching of the waveguide 1111 that emits light.

In the technology according to the present disclosure, the distance measuring device 1 emits the emission light Tx from the optical antenna 111 provided in a semiconductor layer of Si or the like to the object 2, and receives the reflected light Rx from the object 2 by the same optical antenna 111. Accordingly, it is desirable that the optical system of the distance measuring device 1 suppress the spread of the emission light Tx and enlarge an effective opening of light reception. Hereinafter, the technology according to the present disclosure conceived on the basis of the above circumstances will be described separately in a first embodiment and a second embodiment. Such an optical antenna 111 and an optical system provided on the optical antenna 111 are also collectively referred to as a light deflecting device.

### 2. First Embodiment

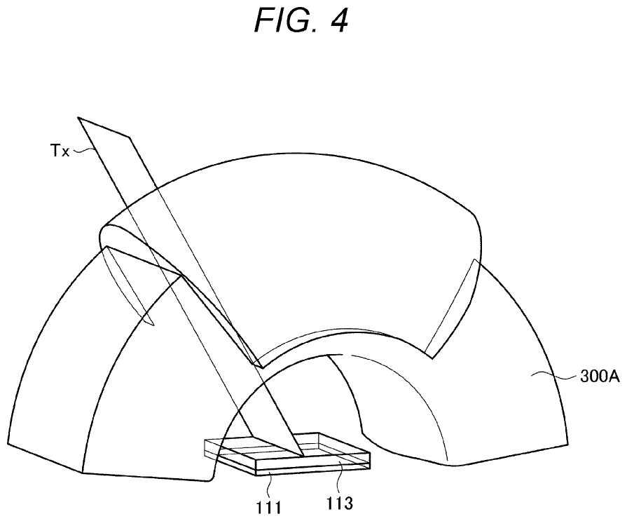

First, a technology according to the first embodiment of the present disclosure will be described with reference to FIGS. 4 to 26. The first embodiment of the present disclosure is an embodiment in which the spread of the emission light Tx emitted from the distance measuring device 1 is suppressed and the effective opening of light reception is enlarged by controlling the shape and the like of the module lens provided over a plurality of waveguides on the optical antenna 111.

### 2.1. First Shape Example

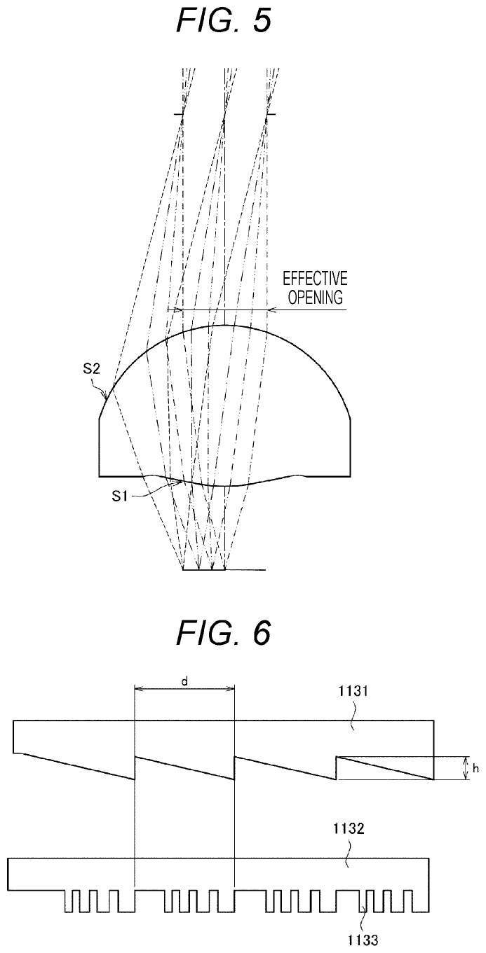

FIG. 4 is a perspective view illustrating a shape of a module lens 300A according to a first shape example. FIG. 5 is a vertical cross-sectional view illustrating a cross-sectional shape of the module lens 300A illustrated in FIG. 4. FIG. 6 is a vertical cross-sectional view illustrating a configuration of a diffraction grating 113 provided on the optical antenna 111.

As illustrated in FIG. 4, the module lens 300A according to a first shape example is a donut-shaped prism having an annular shape in which a circumferential body is rotated by a rotation axis extending in the second direction orthogonal to the first direction in which the waveguide of the optical antenna 111 extends. The module lens 300A according to the first shape example can shape the emission light Tx into a light beam substantially parallel to the ϕ direction.

Specifically, the module lens 300A has a shape in which the cross-sectional shape illustrated in FIG. 5 is rotated by a rotation axis extending in the second direction. The cross-sectional shape illustrated in FIG. 5 is, for example, a shape in which an aspheric surface coefficient of a lower surface S1 facing the optical antenna 111 is represented by the following Table 1, and the aspheric surface coefficient of an upper surface S2 facing the outside of the module lens 300A is represented by the following Table 2, whereby the emission light Tx emitted from the optical antenna 111 can be formed into a light beam substantially parallel to the ϕ direction. The annular shape of the module lens 300A can be formed by rotating a figure drawn according to the following Mathematical Expression 1 about (X, Y, Z)=(0, 0, 0) about the Y axis using the coefficients illustrated in Tables 1 and 2. Note that the refractive index of the module lens 300A is 1.5.

TABLE 1

| | |
|---|---|
| Y curvature radius | −11.82131444 |
| Conic constant (k) | 0.00E+00 |
| Fourth order coefficient (A) | 5.43E−04 |
| Sixth order coefficient (B) | 5.50E−06 |
| Eighth order coefficient (C) | −2.77E−07 |
| Tenth order coefficient (D) | 4.91E−09 |

TABLE 2

| | |
|---|---|
| Y curvature radius | 9.039775277 |
| Conic constant (k) | −0.280484803 |
| Fourth order coefficient (A) | −8.24E−05 |
| Sixth order coefficient (B) | 3.30E−07 |
| Eighth order coefficient (C) | −4.22E−09 |
| Tenth order coefficient (D) | 5.06E−11 |

$$\begin{matrix}Mathematical Expression 1 & \\ z = \frac{\frac{{x}^{2}}{r}}{1 + \sqrt{1 - \frac{( 1 + k ) {x}^{2}}{{r}^{2}}}} + {Ax}^{4} + B {x}^{6} + C {x}^{8} + D {x}^{10} & [ Math . 1 ]\end{matrix}$$

Furthermore, the diffraction grating 113 is provided between the module lens 300A and the optical antenna 111. The diffraction grating 113 is a linear diffraction grating capable of bending the emission light Tx emitted from the optical antenna 111 in the first direction (θ direction). For example, the diffraction grating 113 is provided with a Z distance of 0.3 mm from a light emitting point, a thickness of 0.7 mm, a refractive index of 1.5, and a cross-sectional shape illustrated in FIG. 6, so that the emission light Tx having an incident angle of 10 deg in the θ direction can be diffracted and emitted at an emission angle of 0 deg in the θ direction. That is, the diffraction grating 113 can diffract the incident light by 10 deg in the θ direction. Since the emission light Tx emitted from the photonic crystal waveguide 1110 is emitted while being inclined in the propagation direction (first direction) of the light to the photonic crystal waveguide 1110, the diffraction grating 113 can radiate the emission light Tx directly upward from the optical antenna 111 by correcting the inclination in the θ direction of the emission light Tx.

As illustrated in FIG. 6, the cross-sectional structure of the diffraction grating 113 may be a blaze structure 1131 in which a diffraction pitch d in the θ direction is 8.92 μm and a height h of a saw tooth is 3.1 μm. In addition, the cross-sectional shape of the diffraction grating 113 may be a metalens structure 1132 using dielectric pillars 1133 having a diffraction pitch d of 8.92 μm in the 8 direction. The dielectric pillars 1133 include, for example, amorphous silicon, TiO₂, or the like, and can give a phase to the emission light Tx by changing the size of the diameter.

Note that the diffraction grating 113 may be provided such that an uneven surface that diffracts the emission light Tx faces the optical antenna 111 side as illustrated in FIG. 6, or may be provided such that an uneven surface that diffracts the emission light Tx faces the module lens 300A side.

The optical antenna 111 includes a plurality of waveguides extending in the first direction (θ direction) with a width of 5 μm and a length of 1 mm. The plurality of waveguides included in the optical antenna 111 is provided in parallel to each other in the second direction (ϕ direction) at a pitch of 255 μm. The optical antenna 111 may emit emission light Tx from each of the waveguides.

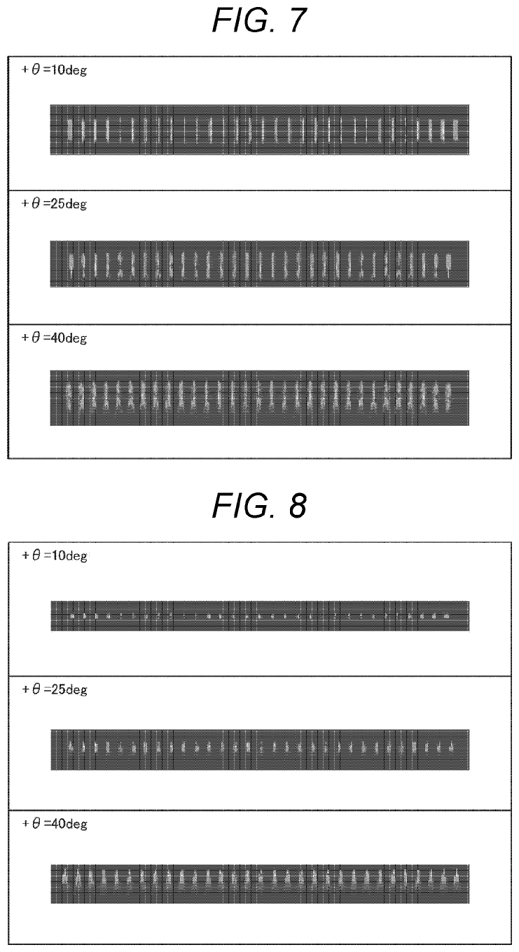

FIG. 7 illustrates a spot shape of the emission light Tx emitted through the diffraction grating 113 and the module lens 300A described with reference to FIGS. 4 to 6. As illustrated in FIG. 7, the module lens 300A according to the first shape example can obtain a clean spot shape in which the emission light Tx from each of the waveguides is separated from each other at each of the emission angles of 10 deg, 25 deg, and 40 deg in the θ direction from the optical antenna 111. Furthermore, the module lens 300A according to the first shape example has an effective opening of 7.8 mm, and thus a large effective opening can be obtained.

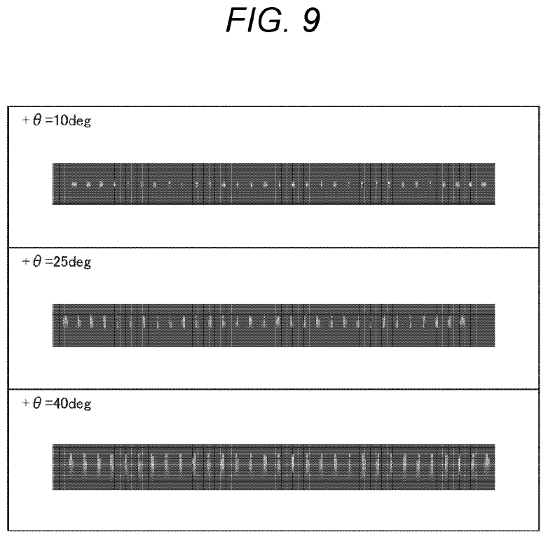

Here, the spot shape of the emission light Tx in a case where the emission light Tx emitted from the optical antenna 111 is further condensed in the θ direction is illustrated in FIGS. 8 and 9. In the spot shape illustrated in FIG. 8, the emission light Tx emitted from the optical antenna 111 is condensed such that the focal length in the θ direction is 33.3 mm. Furthermore, in the spot shape illustrated in FIG. 9, the emission light Tx emitted from the optical antenna 111 is condensed such that the focal length in the θ direction becomes 33.3 mm, and the width in the θ direction of the waveguide that emits the emission light Tx is further reduced to half (0.5 mm).

Note that condensing of the emission light Tx in the 0 direction can be performed, for example, by arranging a cylindrical lens in the θ direction, a metalens in the 0 direction, or a diffractive lens in the θ direction between the optical antenna 111 and the module lens 300A.

As illustrated in FIG. 8, by condensing the emission light Tx in the θ direction, the module lens 300A according to the first shape example can obtain a cleaner spot shape. In the spot shape illustrated in FIG. 8, the maximum light density in the spot shape is improved, and thus it is possible to improve an SN ratio of the reflected light Rx received by the optical antenna 111.

As illustrated in FIG. 9, by further reducing the θ-direction width of the waveguide that emits the emission light Tx, the module lens 300A according to the first shape example can obtain a clearer spot shape. In the spot shape illustrated in FIG. 9, the maximum light density in the spot shape is further improved, and thus it is possible to further improve the SN ratio of the reflected light Rx received by the optical antenna 111.

### 2.2. Second Shape Example

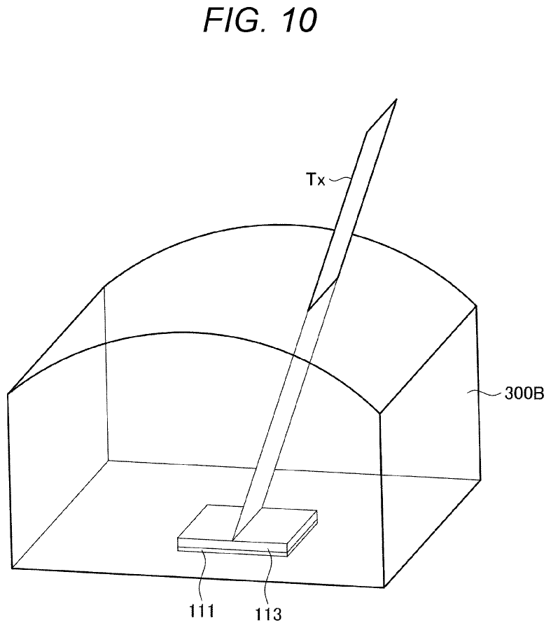

FIG. 10 is a perspective view illustrating a shape of a module lens 300B according to a second shape example.

As illustrated in FIG. 10, the module lens 300B according to the second shape example is a metalens having a curvature condensing characteristic, and forms the emission light Tx emitted from the optical antenna 111 through the diffraction grating 113 into a light beam substantially parallel to the ϕ direction. Specifically, in the module lens 300B according to the second shape example, a metalens having a planar structure with a period smaller than the wavelength of the emission light Tx is provided on an outer peripheral surface of a cylinder extending in the second direction orthogonal to the first direction in which the waveguide of the optical antenna 111 extends. The metalens is a planar lens that imparts a phase to the incident light by a planar structure having a period smaller than the wavelength of the emission light Tx. The module lens 300B can shape the emission light Tx into a light beam substantially parallel to the ϕ direction by imparting a phase to the emission light Tx by a metalens provided on a curved surface corresponding to the outer peripheral surface of the cylinder.

### 2.3. Third Shape Example

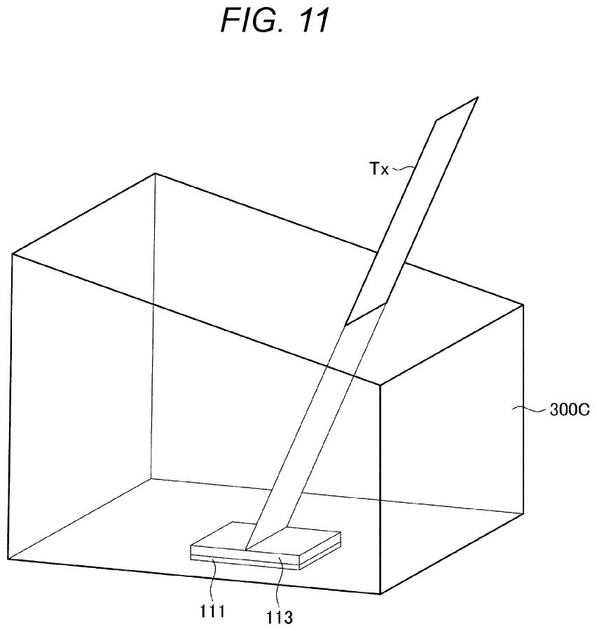

FIG. 11 is a perspective view illustrating a shape of a module lens 300C according to a third shape example.

As illustrated in FIG. 11, the module lens 300C according to the third shape example is a metalens having a slope condensing characteristic, and shapes the emission light Tx emitted from the optical antenna 111 into a light beam substantially parallel to the ϕ direction. Specifically, in the module lens 300C according to the third shape example, a metalens having a planar structure with a period smaller than the wavelength of the emission light Tx is provided on a slope surface inclined in the first direction in which the waveguide of the optical antenna 111 extends. As described above, the metalens is a planar lens that imparts a phase to the incident light by the planar structure having a period smaller than the wavelength of the emission light Tx. The module lens 300C can shape the emission light Tx into a light beam substantially parallel to the ϕ direction by imparting a phase to the emission light Tx by the metalens provided on the slope surface.

### 2.4. Fourth Shape Example

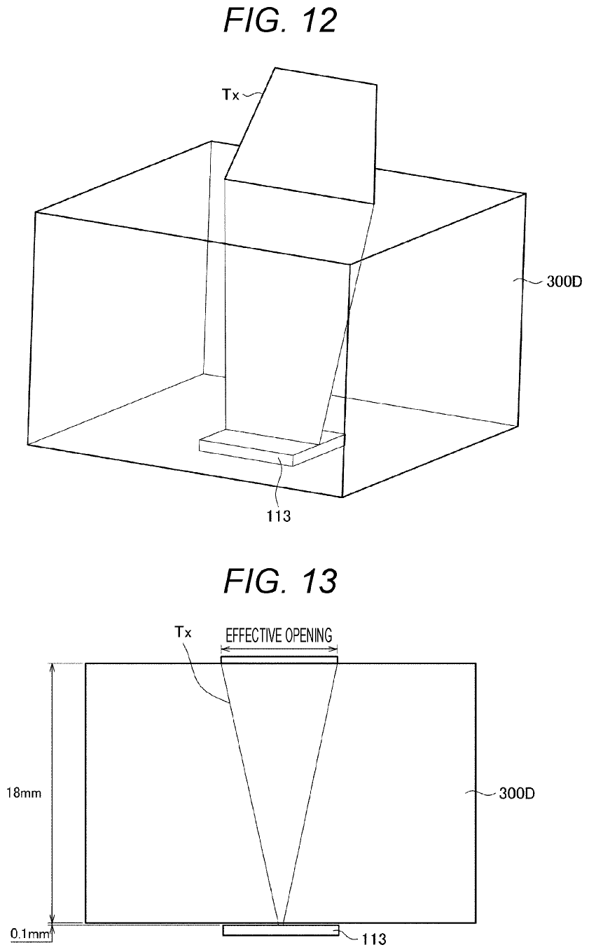

FIG. 12 is a perspective view illustrating a shape of a module lens 300D according to a fourth shape example. FIG. 13 is a vertical cross-sectional view illustrating a cross-sectional shape of the module lens 300D illustrated in FIG. 12.

As illustrated in FIG. 12, in the module lens 300D according to the fourth shape example, a metalens having a planar structure with a period smaller than the wavelength of the emission light Tx is provided on an upper surface of a rectangular parallelepiped shape. The module lens 300D can shape the emission light Tx emitted from the optical antenna 111 through the diffraction grating 113 into a light beam substantially parallel to the ϕ direction.

Specifically, as illustrated in FIG. 13, the module lens 300D has a rectangular parallelepiped shape with a height of 18 mm, and is provided with a space of 0.1 mm from the diffraction grating 113. Coefficients of a phase difference function of the metalens formed in the module lens 300D are represented in the following Table 3. The metalens formed in the module lens 300D is provided so as to impart a phase difference amount Φ to be imparted expressed by the following Mathematical Expression 2 to the emission light Tx using the coefficients illustrated in Table 3. Note that the refractive index of the module lens 300D is 1.5.

TABLE 3

| | Value |
|---|---|
| Reference wavelength λ0 [nm] | 1550 |
| C (X2) | 3.8760E−02 |
| C (X2Y) | 3.8760E−04 |
| C (X4) | −2.8750E−06 |
| C (X4Y) | −8.6249E−08 |
| C (X4Y2) | −8.6250E−10 |
| C (X4Y3) | −2.8750E−12 |

$$\begin{matrix}Mathematical Expression 2 & \\ Φ = \frac{{C}_{x 2} {x}^{2} + {C}_{x 2 y} {x}^{2} y + {C}_{x 4} {x}^{4} + {C}_{x 4 y} {x}^{4} y + {C}_{x 4 y 2} {x}^{4} {y}^{2} + {C}_{x 4 y 3} {x}^{4} {y}^{3}}{{λ}_{0}} & [ Math . 1 ]\end{matrix}$$

Conditions of the emission light Tx emitted from the optical antenna 111 and the specifications of the diffraction grating 113 are similar to those of the first shape example, and thus the description thereof is omitted here.

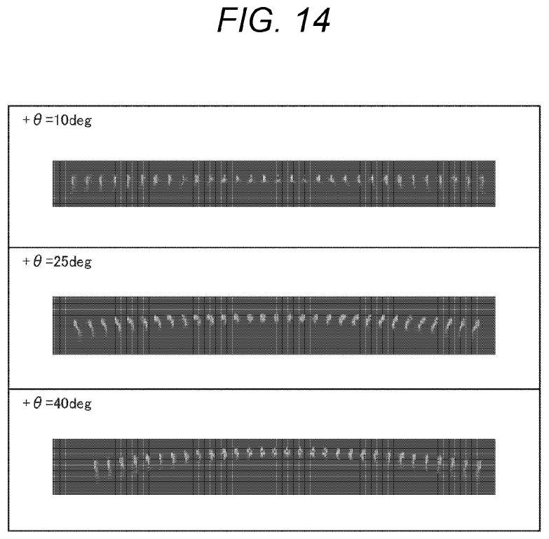

FIG. 14 illustrates a spot shape of the emission light Tx emitted through the diffraction grating 113 and the module lens 300D described with reference to FIGS. 12 and 13. As illustrated in FIG. 14, the module lens 300D according to the fourth shape example can obtain a more condensed spot shape in which the emission light Tx from each of the waveguides is separated from each other at each of the emission angles of 10 deg, 25 deg, and 40 deg in the 8 direction from the optical antenna 111. Furthermore, the module lens 300D according to the fourth shape example has an effective opening of 8 mm, and thus a large effective opening can be obtained. Therefore, the module lens 300D according to the fourth shape example can improve the condensing property of the emission light Tx while further simplifying the shape of the lens.

### 2.5. Fifth Shape Example

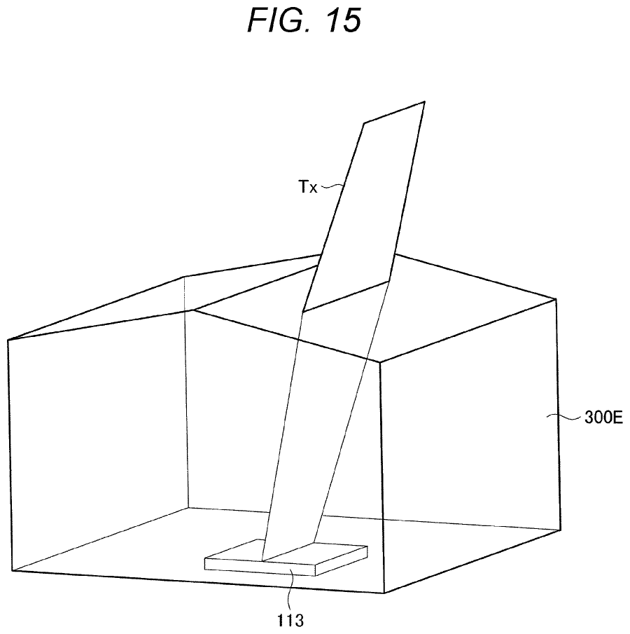

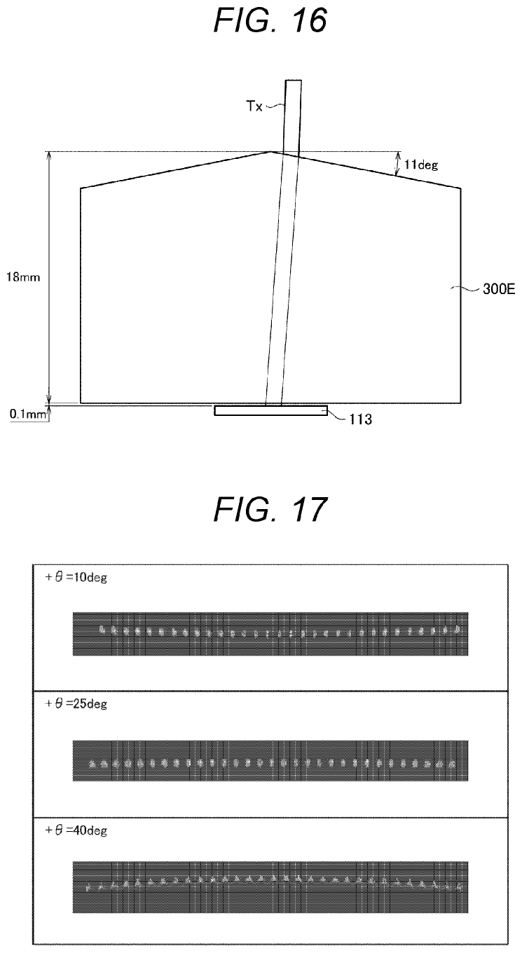

FIG. 15 is a perspective view illustrating a shape of a module lens 300E according to a fifth shape example. FIG. 16 is a vertical cross-sectional view illustrating a cross-sectional shape of the module lens 300E illustrated in FIG. 15.

As illustrated in FIG. 15, in the module lens 300E according to the fifth shape example, a metalens having a planar structure with a period smaller than the wavelength of the emission light Tx is provided on an inclined upper surface of a rectangular parallelepiped shape. The module lens 300E can shape the emission light Tx emitted from the optical antenna 111 through the diffraction grating 113 into a light beam substantially parallel to the ϕ direction.

Specifically, as illustrated in FIG. 15, the module lens 300E has a rectangular parallelepiped shape with a height of 18 mm, and is provided with a space of 0.1 mm from the diffraction grating 113. Furthermore, the module lens 300E is provided such that upper surfaces of the rectangular parallelepiped shape are inclined downward by 11 deg toward both sides in the first direction. Coefficients of the phase difference function of the metalens formed in the module lens 300E are represented in the following Table 4. The metalens formed in the module lens 300E is provided so as to impart the phase difference amount Φ to be imparted expressed by the following Mathematical Expression 3 to the emission light Tx using the coefficients illustrated in Table 4. Note that the refractive index of the module lens 300E is 1.5.

TABLE 4

| | Value |
|---|---|
| Reference wavelength λ0 [nm] | 1550 |
| C (X2) | 3.8760E−02 |
| C (X4) | 3.8760E−04 |
| C (X6) | −2.8750E−06 |
| C (X8) | −8.6249E−08 |
| C (X10) | −8.6250E−10 |

$$\begin{matrix}Mathematical Expression 3 & \\ Φ = \frac{{C}_{x 2} {x}^{2} + {C}_{x 4} {x}^{4} + {C}_{x 6} {x}^{6} + {C}_{x8} {x}^{8} + {C}_{x 10} {x}^{10}}{{λ}_{0}} & [ Math . 3 ]\end{matrix}$$

Conditions of the emission light Tx emitted from the optical antenna 111 are similar to those of the first shape example, and thus the description thereof is omitted here. In the diffraction grating 113, by setting the diffraction pitch d in the θ direction to 26.7 μm, the diffraction angle of the incident light in the θ direction is set to 3.3 deg.

FIG. 17 illustrates a spot shape of the emission light Tx emitted through the diffraction grating 113 and the module lens 300E described with reference to FIGS. 15 and 16. As illustrated in FIG. 17, the module lens 300E according to the fifth shape example can obtain a more condensed spot shape in which the emission light Tx from each of the waveguides is separated from each other at each of the emission angles of 10 deg, 25 deg, and 40 deg in the θ direction from the optical antenna 111. Furthermore, the module lens 300E according to the fifth shape example has an effective opening of 7.6 mm, and thus a large effective opening can be obtained. Therefore, the module lens 300E according to the fifth shape example can improve the condensing property of the emission light Tx while further simplifying the shape of the lens.

### 2.6. Sixth Shape Example

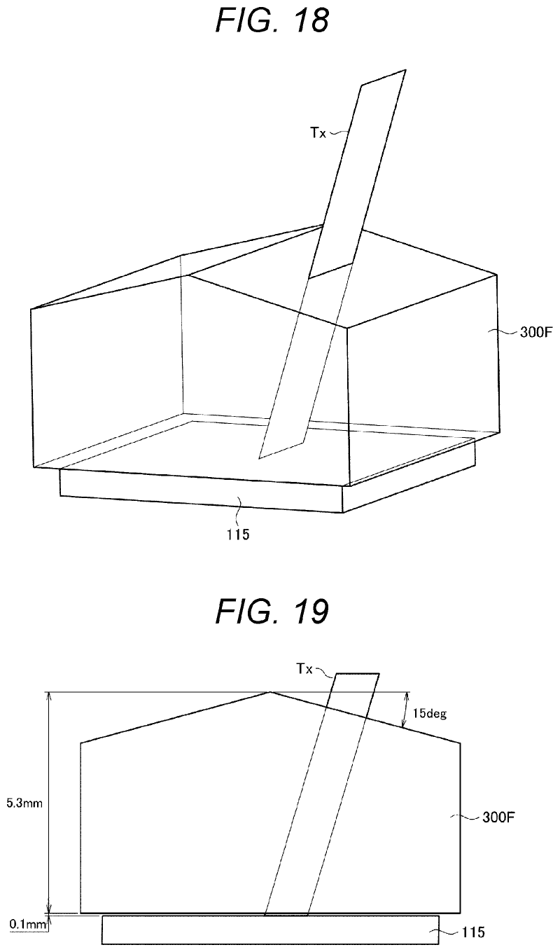

FIG. 18 is a perspective view illustrating a shape of a module lens 300F according to a sixth shape example. FIG. 19 is a vertical cross-sectional view illustrating a cross-sectional shape of the module lens 300F illustrated in FIG. 18.

As illustrated in FIG. 18, in the module lens 300F according to the sixth shape example, a metalens having a planar structure with a period smaller than the wavelength of the emission light Tx is provided on an inclined upper surface of a rectangular parallelepiped shape. The module lens 300F can shape the emission light Tx emitted from the optical antenna 111 through a dummy substrate 115 into a light beam substantially parallel to the ϕ direction. In the module lens 300F according to the sixth shape example, by narrowing the pitch in the ϕ direction of the waveguide included in the optical antenna 111, the emission light Tx can be formed into a light beam substantially parallel to the ϕ direction by an optical system having a smaller size.

Specifically, as illustrated in FIG. 18, the module lens 300F has a rectangular parallelepiped shape with a height of 5.3 mm, and is provided with a space of 0.1 mm from the dummy substrate 115. The dummy substrate 115 is a transparent substrate that transmits the emission light Tx. Furthermore, the module lens 300F is provided such that upper surfaces of the rectangular parallelepiped shape are inclined downward by 15 deg toward both sides in the first direction. Coefficients of the phase difference function of the metalens formed in the module lens 300F are represented in the following Table 5. The metalens formed in the module lens 300F is provided so as to impart the phase difference amount Φ to be imparted expressed by the above Mathematical Expression 3 to the emission light Tx using the coefficients illustrated in Table 5. Note that the refractive index of the module lens 300F is 1.5.

TABLE 5

| | Value |
|---|---|
| Reference wavelength λ0 [nm] | 1550 |
| C (X2) | 1.16279E−01 |
| C (X4) | 3.51564E−06 |
| C (X6) | −2.53811E−06 |
| C (X8) | −1.15389E−06 |
| C (X10) | 8.87881E−36 |

As compared with the first shape example, the optical antenna 111 is provided with 75 μm in which the pitch in the ϕ direction of the waveguide included in the optical antenna 111 is narrowed to ⅓. Other conditions of the optical antenna 111 are similar to those of the first shape example, and thus description thereof is omitted here.

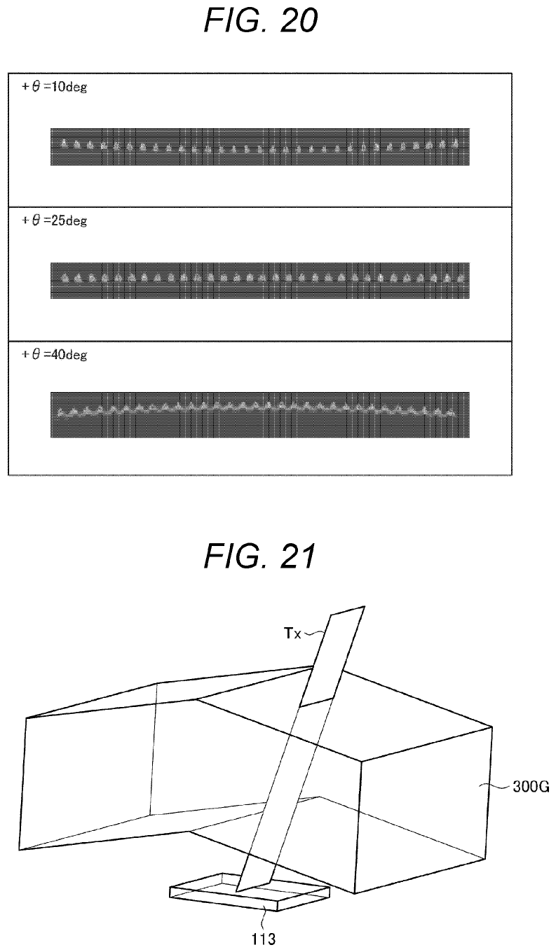

FIG. 20 illustrates a spot shape of the emission light Tx emitted through the module lens 300F described with reference to FIGS. 18 and 19. As illustrated in FIG. 20, the module lens 300F according to the sixth shape example can obtain a spot shape in which the emission light Tx from each waveguide is condensed at each of the emission angles of 10 deg, 25 deg, and 40 deg in the θ direction from the optical antenna 111. Furthermore, although the module lens 300F according to the sixth shape example has an effective opening of 2.6 mm, the height of the optical system can be greatly reduced. Therefore, the module lens 300F according to the sixth shape example can further downsize the distance measuring device 1.

### 2.7. Seventh Shape Example

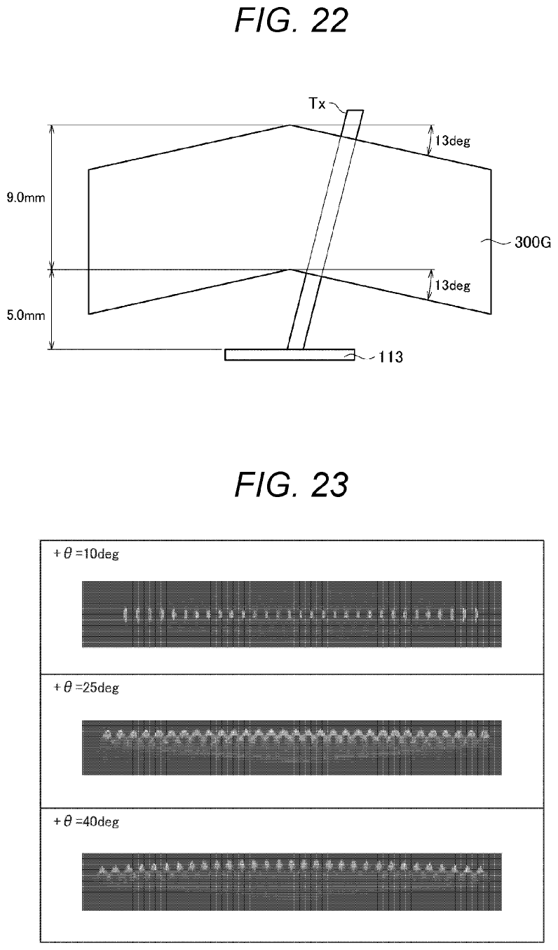

FIG. 21 is a perspective view illustrating a shape of a module lens 300G according to a seventh shape example. FIG. 22 is a vertical cross-sectional view illustrating a cross-sectional shape of the module lens 300G illustrated in FIG. 21.

As illustrated in FIG. 21, in the module lens 300G according to the seventh shape example, a metalens having a planar structure with a period smaller than the wavelength of the emission light Tx is provided on both an inclined upper surface and lower surface of a rectangular parallelepiped shape. The module lens 300G can shape the emission light Tx emitted from the optical antenna 111 through the diffraction grating 113 into a light beam substantially parallel to the ϕ direction. In the module lens 300G according to the seventh shape example, by narrowing the pitch in the ϕ direction of the waveguide included in the optical antenna 111, the emission light Tx can be formed into a light beam substantially parallel to the ϕ direction by the optical system having a smaller size.

Specifically, as illustrated in FIG. 21, the module lens 300G has a rectangular parallelepiped shape with a height of 9.0 mm, and is provided with a space of 5.0 mm from the diffraction grating 113. Furthermore, the module lens 300G is provided such that upper surfaces and lower surfaces of the rectangular parallelepiped shape are inclined downward by 13 deg toward both sides in the first direction. Coefficients of the phase difference function of the metalens formed in the module lens 300G are represented in the following Table 6. The metalens formed in the module lens 300G is provided so as to impart the phase difference amount Φ to be imparted expressed by the above Mathematical Expression 3 to the emission light Tx using the coefficients illustrated in Table 6. Note that the refractive index of the module lens 300F is 1.5.

TABLE 6

| | Upper surface | Lower surface |
|---|---|---|
| Reference wavelength | 1550 | 1550 |
| λ0 [nm] | | |
| C (X2) | 9.0508E−03 | 7.68110E−02 |
| C (X4) | −4.4813E−04 | −7.95429E−05 |
| C (X6) | −1.0756E−05 | 1.76103E−05 |
| C (X8) | 4.2196E−07 | −7.58293E−07 |
| C (X10) | −1.4357E−08 | 5.53432E−09 |

As compared with the first shape example, the optical antenna 111 is provided with 112.5 μm in which the pitch in the j direction of the waveguide included in the optical antenna 111 is narrowed to ½. Furthermore, the light emission angle in the j direction from the waveguide included in the optical antenna 111 is ±30 deg.

FIG. 23 illustrates a spot shape of the emission light Tx emitted through the diffraction grating 113 and the module lens 300G described with reference to FIGS. 21 and 22. As illustrated in FIG. 23, the module lens 300G according to the seventh shape example can obtain a spot shape in which the emission light Tx from each waveguide is condensed at each of the emission angles of 10 deg, 25 deg, and 40 deg in the θ direction from the optical antenna 111. Furthermore, the module lens 300G according to the seventh shape example has an effective opening of 7.4 mm, and thus a large effective opening can be obtained. Therefore, the module lens 300G according to the seventh shape example can significantly reduce the height of the optical system while maintaining a large effective opening, and thus the distance measuring device 1 can be further downsized.

### 2.8. Eighth Shape Example

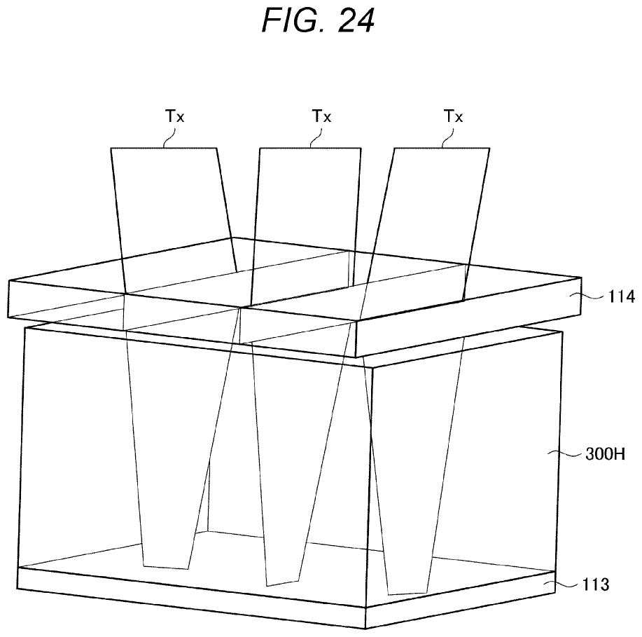

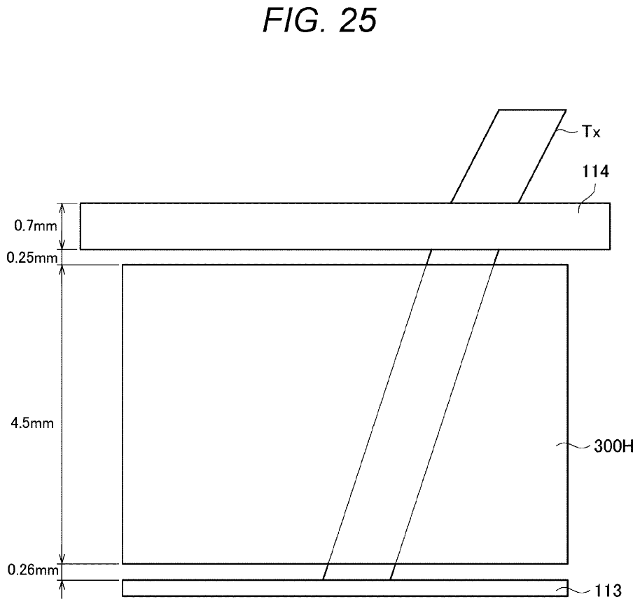

FIG. 24 is a perspective view illustrating a shape of a module lens 300H according to an eighth shape example. FIG. 25 is a vertical cross-sectional view illustrating a cross-sectional shape of the module lens 300H illustrated in FIG. 24.

As illustrated in FIG. 24, in the module lens 300H according to the eighth shape example, a metalens having a planar structure with a period smaller than the wavelength of the emission light Tx is provided on each of upper surfaces of three divided rectangular parallelepiped shapes. The module lens 300H can shape the emission light Tx emitted from the optical antenna 111 obtained by dividing the waveguide into three groups through the diffraction grating 113 into light beams substantially parallel to the ϕ direction. The emission light Tx shaped by the module lens 300H is further diffracted by a three-divided diffraction grating 114 to be uniformly dispersed. In the module lens 300H according to the eighth shape example, the waveguide included in the optical antenna 111 is divided into three groups in the ϕ direction, and the emission light Tx emitted from the waveguides belonging to the respective groups can be formed into light beams substantially parallel to the ϕ direction by different metalenses.

Specifically, as illustrated in FIG. 25, the module lens 300H has a rectangular parallelepiped shape divided into three with a height of 4.5 mm, and is provided with a space of 0.26 mm from the diffraction grating 113. Furthermore, on the module lens 300H, the diffraction grating 114 divided into three with a thickness of 0.7 mm is provided with a space of 0.25 mm. Coefficients of the phase difference function of the metalens formed by dividing the module lens 300H into three are represented in the following Table 7. The metalens formed in the module lens 300H is provided so as to impart the phase difference amount Φ to be imparted expressed by the above Mathematical Expression 3 to the emission light Tx using the coefficients illustrated in Table 7. Note that the refractive index of the module lens 300H is 1.5.

TABLE 7

| | Center | + side | − side |
|---|---|---|---|
| Reference | 1550 | 1550 | 1550 |
| wavelength 20 | | | |
| [nm] | | | |
| X shift amount | 0 | 2.5 | −2.5 |
| [mm] | | | |
| C (X2) | 1.5504E−01 | 1.5504E−01 | 1.5504E−01 |
| C (X4) | 6.2016E−03 | 6.2016E−03 | 6.2016E−03 |
| C (X6) | −1.8400E−04 | −1.8400E−04 | −1.8400E−04 |
| C (X8) | −2.2080E−05 | −2.2080E−05 | −2.2080E−05 |
| C (X10) | −8.8320E−07 | −8.8320E−07 | −8.8320E−07 |

As compared with the first shape example, the optical antenna 111 is provided to be divided into three groups in the ϕ direction with the pitch in the ϕ direction of the waveguide included in the optical antenna 111 being 56 μm. The three groups are each provided at a distance of 2.5 mm.

Similarly, the diffraction grating 114 is divided into three portions. The center diffraction grating 114 transmits the emission light Tx from the center module lens 300H without diffraction. The diffraction pitch d of the diffraction grating 114 on a + side is 8.92 μm, and the emission light Tx from the module lens 300H on the + side can be further diffracted to the + side in the ϕ direction. The diffraction pitch d of the diffraction grating 114 on a − side is 8.92 μm, and the emission light Tx from the module lens 300H on the − side can be further diffracted to the − side in the ϕ direction.

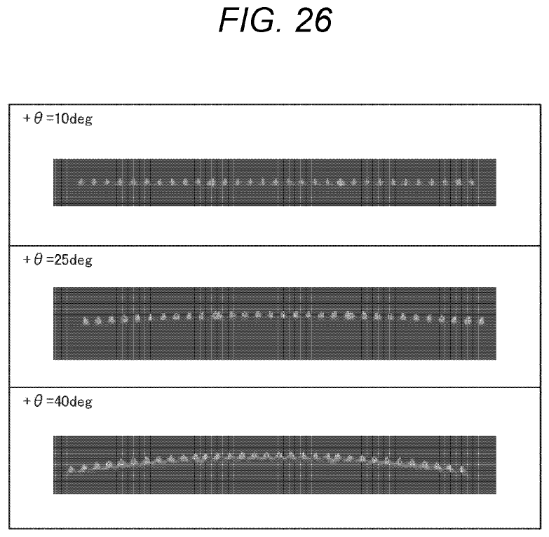

FIG. 26 illustrates spot shapes of the emission light Tx emitted through the diffraction grating 113, the module lens 300H, and the diffraction grating 114 described with reference to FIGS. 24 and 25. As illustrated in FIG. 26, the module lens 300H according to the eighth shape example can obtain a spot shape in which the emission light Tx from each waveguide is condensed at each of the emission angles 10 deg, 25 deg, and 40 deg in the θ direction from the optical antenna 111. Furthermore, the module lens 300H according to the eighth shape example has an effective opening of 2.1 mm×3, and thus a large effective opening can be obtained. Therefore, the module lens 300H according to the eighth shape example can significantly reduce the height of the optical system while maintaining the large effective opening, and thus the distance measuring device 1 can be further downsized.

### 2.9. Appendix

In the second to eighth shape examples described above, the metalens are provided on the upper surfaces of the module lenses 300B to 300H, but the technology according to the present disclosure is not limited to the above examples. For example, a diffractive lens may be provided on the module lenses 300B to 300H instead of the metalens. Furthermore, in the second to eighth shape examples described above, it is also possible to obtain a more favorable spot shape by slightly condensing the emission light Tx incident on the module lenses 300B to 300H in the θ direction.

Moreover, in the above description, the diffraction grating 113 is used to bend the emission light Tx in the θ direction, but the technology according to the present disclosure is not limited to the above example. For example, the emission light Tx may be bent in the θ direction using a prism instead of the diffraction grating 113.

### 3. Second Embodiment

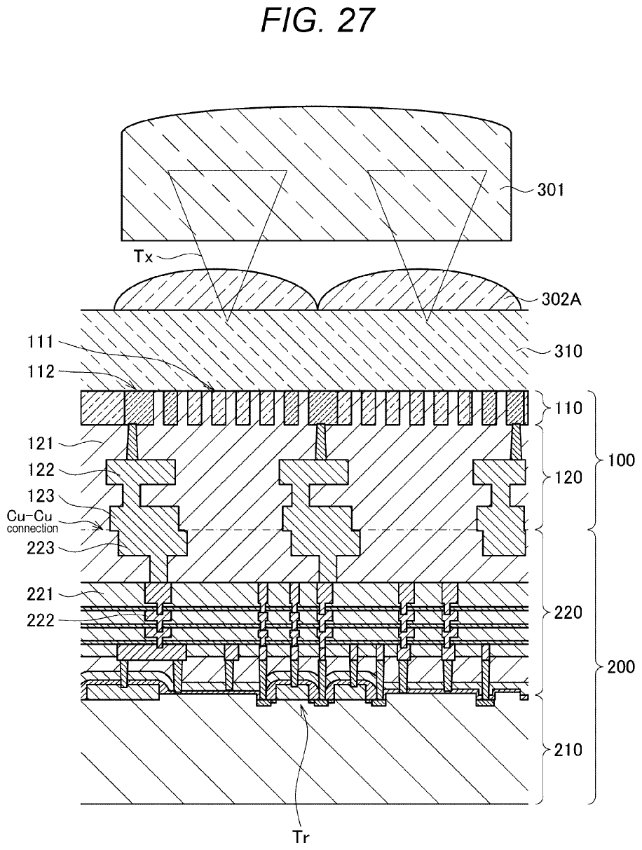

Next, a technology according to the second embodiment of the present disclosure will be described with reference to FIGS. 27 to 36. The second embodiment of the present disclosure is an embodiment in which an on-chip lens is provided on the optical antenna 111 in addition to the module lens to suppress the spread of the emission light Tx emitted from the distance measuring device 1.

### 3.1. First Configuration Example

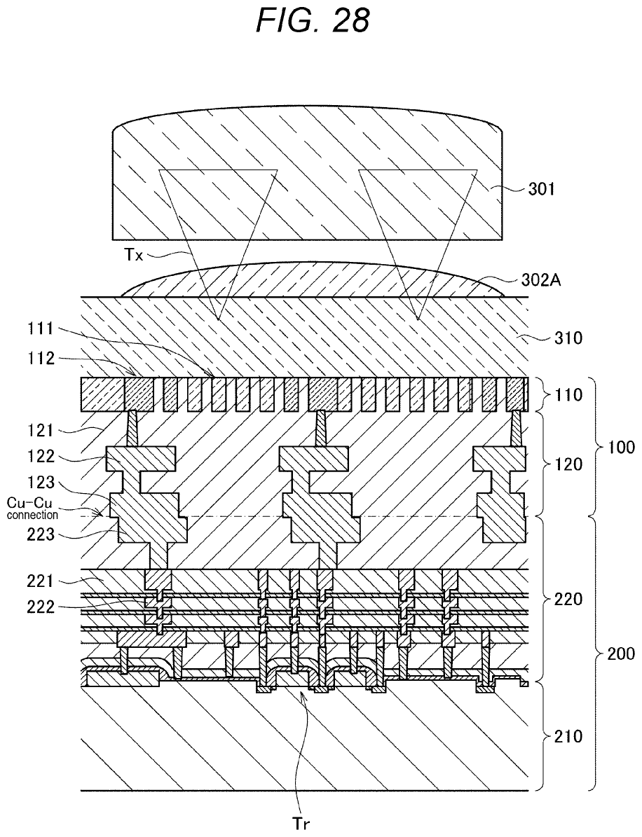

FIGS. 27 and 28 are vertical cross-sectional views illustrating configurations of an on-chip lens 302A and the module lens 301 according to the first configuration example.

As illustrated in FIGS. 27 and 28, the on-chip lens 302A is provided on the planarization film 310, and is provided for each waveguide included in the optical antenna 111 or for each plurality of waveguides. For example, the on-chip lens 302A may be provided as a cylindrical lens array. In addition, in a case where the diffraction grating 113 is provided on the optical antenna 111, the on-chip lens 302A may be provided for each slit or each plurality of slits from which the diffracted light of the diffraction grating 113 is emitted.

The module lens 301 is provided on the on-chip lens 302A and is provided as a convex lens over all the waveguides included in the optical antenna 111. Note that the configurations of the planarization film 310 and the subsequent layers are as described with reference to FIG. 2, and thus the description thereof is omitted here.

In the first configuration example, the emission light Tx from the optical antenna 111 can be shaped into light beams substantially parallel to the ϕ direction in stages by the two lenses of the on-chip lens 302A and the module lens 301. According to the first configuration example, the distance measuring device 1 can shape the emission light Tx into a light beam substantially parallel to the ϕ direction even in a case where the lens power of each of the on-chip lens 302A and the module lens 301 is small.

### 3.2. Second Configuration Example

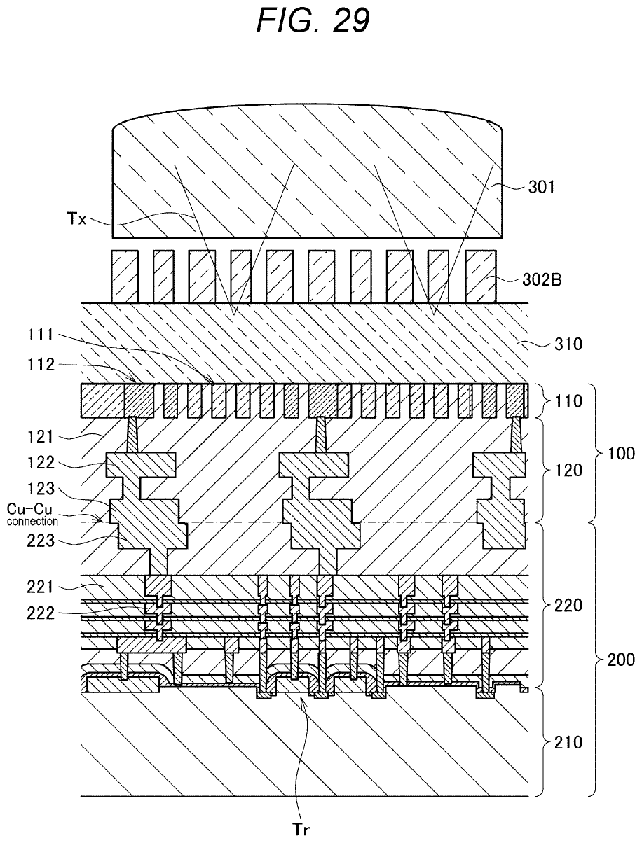

FIG. 29 is a vertical cross-sectional view illustrating a configuration of the on-chip lens 302B and the module lens 301 according to the second configuration example.

As illustrated in FIG. 29, the on-chip lens 302B is provided on the planarization film 310, and is provided for each waveguide included in the optical antenna 111 or for each of a plurality of waveguides. For example, the on-chip lens 302B is provided as a metalens in which a planar structure having a period smaller than the wavelength of the emission light Tx is formed.

The module lens 301 is provided on the on-chip lens 302B, and is provided as a convex lens over all the waveguides included in the optical antenna 111. Note that the configurations of the planarization film 310 and the subsequent layers are as described with reference to FIG. 2, and thus the description thereof is omitted here.

In the second configuration example, the emission light Tx from the optical antenna 111 can be shaped into light beams substantially parallel to the ϕ direction in stages by the two lenses of the on-chip lens 302B and the module lens 301. According to the second configuration example, even in a case where the lens power of each of the on-chip lens 302B and the module lens 301 is small, the distance measuring device 1 can shape the emission light Tx into a light beam substantially parallel to the ϕ direction. Furthermore, in a case where the on-chip lens 302B is provided as a metalens, the height of the on-chip lens 302B can be further reduced, and thus the distance measuring device 1 can be more easily downsized.

### 3.3. Third Configuration Example

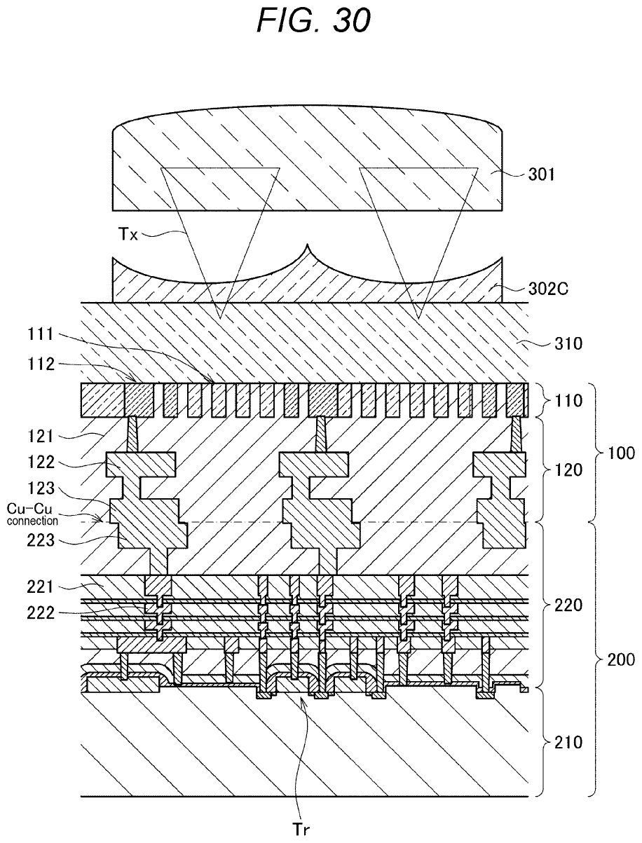

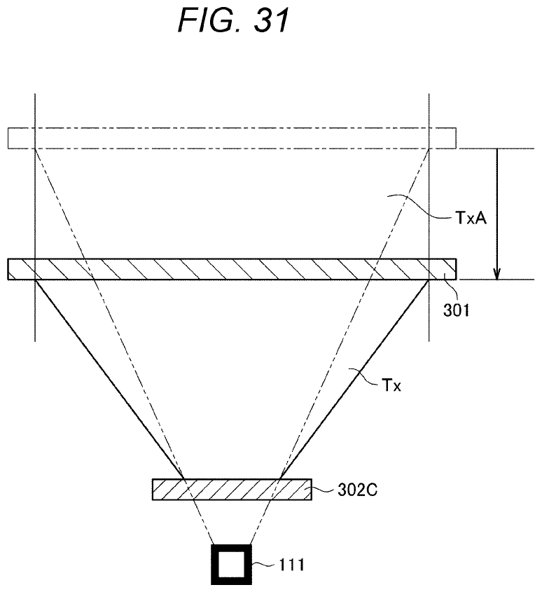

FIG. 30 is a vertical cross-sectional view illustrating a configuration of the on-chip lens 302C and the module lens 301 according to the third configuration example. FIG. 31 is an explanatory diagram describing effects by the on-chip lens 302C and the module lens 301.

As illustrated in FIG. 30, the on-chip lens 302C is provided as a concave lens on the planarization film 310, and is provided for each waveguide included in the optical antenna 111 or for each of a plurality of waveguides. The module lens 301 is provided on the on-chip lens 302C and is provided as a convex lens over all the waveguides included in the optical antenna 111. Note that the configurations of the planarization film 310 and the subsequent layers are as described with reference to FIG. 2, and thus the description thereof is omitted here.

As illustrated in FIG. 31, the emission light Tx from the optical antenna 111 is emitted from the on-chip lens 302C by further widening the beam opening angle by the on-chip lens 302C which is a concave lens. Therefore, in order to cause the emission light Tx having the same beam opening angle as the emission light TxA in the case of not passing through the on-chip lens 302C to be incident, the module lens 301 comes closer to the on-chip lens 302C.

In the third configuration example, by widening the beam opening angle of the emission light Tx from the optical antenna 111 by the on-chip lens 302C that is a concave lens, the distance between the on-chip lens 302C and the module lens 301 can be further shortened. Therefore, the height of the optical system including the on-chip lens 302C and the module lens 301 can be further reduced, and thus the distance measuring device 1 can be further downsized.

### 3.4. Fourth Configuration Example

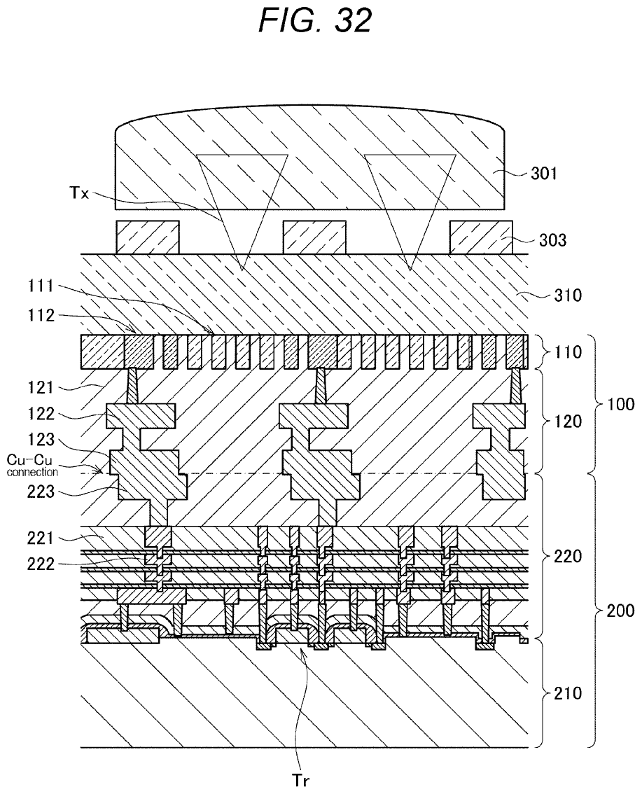

FIG. 32 is a vertical cross-sectional view illustrating a configuration of the condenser lens 303 and the module lens 301 according to the fourth configuration example. FIG. 33 is an explanatory diagram describing effects by the condenser lens 303 and the module lens 301.

As illustrated in FIG. 32, the condenser lens 303 is provided on the planarization film 310, and is provided on both sides of each waveguide included in the optical antenna 111. For example, the condenser lens 303 may be provided as a normal prism lens, or may be provided as a metalens. In addition, the condenser lens 303 may be including a material having a higher refractive index than other optical system members including the module lens 301.

The module lens 301 is provided on the condenser lens 303 and is provided as a convex lens over all the waveguides included in the optical antenna 111. Note that the configurations of the planarization film 310 and the subsequent layers are as described with reference to FIG. 2, and thus the description thereof is omitted here.

As illustrated in FIG. 33, the condenser lens 303 is provided at a position that does not optically affect the emission light Tx emitted from the optical antenna 111. Here, the reflected light Rx reflected by the object 2 is diffused more than the emission light Tx and is incident on the optical antenna 111. At this time, the reflected light Rx diffused more than the emission light Tx is incident on the condenser lens 303 provided on both sides of the waveguide of the optical antenna 111 to be condensed on the waveguide of the optical antenna 111. Therefore, the condenser lens 303 can further improve the condensing efficiency on the optical antenna 111.

In the fourth configuration example, the reflected light Rx can be collected more by the condenser lens 303 provided near the waveguide of the optical antenna 111 and received by the optical antenna 111. Therefore, the distance measuring device 1 can further increase the light receiving sensitivity of the reflected light Rx.

### 3.5. Fifth Configuration Example

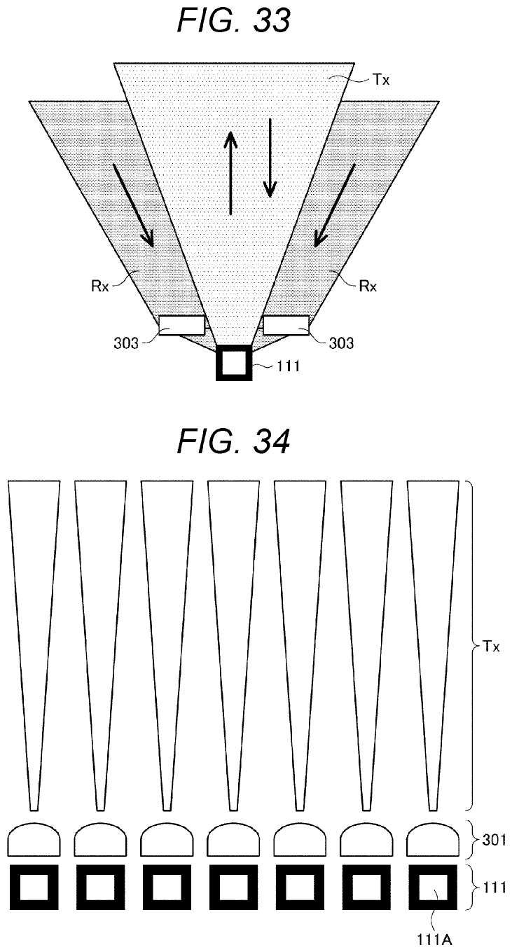

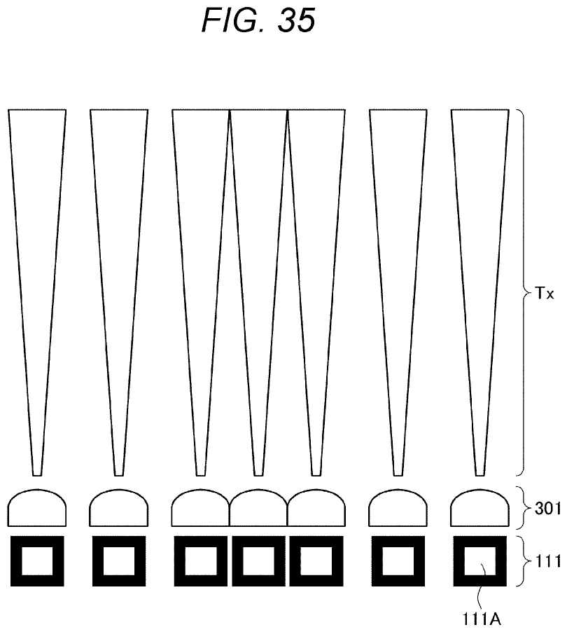

FIGS. 34 to 36 are schematic explanatory diagrams illustrating a positional relationship between the on-chip lens 302 according to the fifth configuration example and the light emitting/receiving unit 111A.

The light emitting/receiving unit 111A is each of emitting units of the emission light Tx emitted from the optical antenna 111 and also is a receiving unit of the reflected light Rx. As an example, the light emitting/receiving unit 111A is each of a plurality of waveguides included in the optical antenna 111. Furthermore, as another example, the light emitting/receiving unit 111A is each of slits that emit diffracted light of the diffraction grating 113 provided on the optical antenna 111.

As illustrated in FIGS. 34 to 36, the on-chip lens 302 may be provided for each of the light emitting/receiving units 111A which are each of the waveguides included in the optical antenna 111 or each of the slits from which the diffracted light of the diffraction grating 113 is emitted.

As illustrated in FIG. 34, the on-chip lens 302 and the light emitting/receiving unit 111A may be uniformly provided over the entire optical antenna 111. In addition, the on-chip lens 302 may be provided immediately above the light emitting/receiving unit 111A.

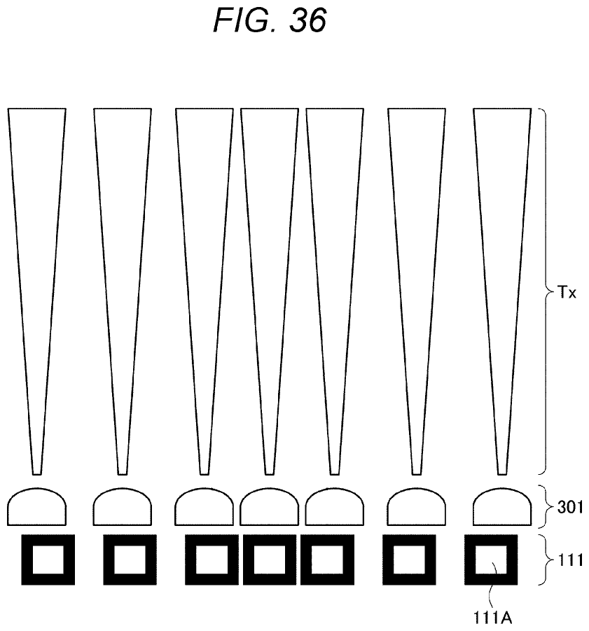

On the other hand, as illustrated in FIG. 35, the on-chip lens 302 and the light emitting/receiving unit 111A may be non-uniformly provided in the entire optical antenna 111. Specifically, the on-chip lens 302 and the light emitting/receiving unit 111A may be provided in such a manner that the density of the on-chip lens 302 and the light emitting/receiving unit 111A is higher in a central portion than in a peripheral portion. In the distance measuring device 1, the importance of the central portion of the visual field, which is likely to be the gaze point, tends to be high, and the importance of the peripheral portion of the visual field tends to be low. Thus, by arranging the on-chip lens 302 and the light emitting/receiving unit 111A at a higher density in the central portion, the distance measuring device 1 can further improve the distance measuring accuracy in the central portion of the visual field.

In addition, as illustrated in FIG. 36, the on-chip lens 302 may be provided at a position offset from the light emitting/receiving unit 111A. Specifically, in a case where the light emitting/receiving unit 111A is arranged at a higher density in the central portion of the visual field, the incidence of the reflected light Rx on the light emitting/receiving unit 111A tends to be oblique in the peripheral portion of the visual field. Thus, by arranging the on-chip lens 302 to be offset toward the peripheral portion side with respect to the light emitting/receiving unit 111A, the reflected light Rx can be made incident on the center of the light emitting/receiving unit 111A.

In the fifth configuration example, the distance measuring device 1 can change the density of the distance measurement information acquired in the visual field by changing the positions of the on-chip lens 302 and the light emitting/receiving unit 111A. Furthermore, the distance measuring device 1 can further improve the light receiving sensitivity of the reflected light Rx by changing the positional relationship between the on-chip lens 302 and the light emitting/receiving unit 111A.

The preferred embodiments of the present disclosure have been described above in detail with reference to the accompanying drawings, but the technical scope of the present disclosure is not limited to such examples. It is apparent that a person having ordinary knowledge in the technical field of the present disclosure can achieve various variations or modifications within the scope of the technical idea recited in claims, and it will be naturally understood that they also belong to the technical scope of the present disclosure.

Furthermore, the effects described in the present specification are merely exemplary or illustrative, and not restrictive. That is, the technology according to the present disclosure can exhibit other effects apparent to those skilled in the art from the description of the present specification, in addition to the effects described above or instead of the effects described above.

Note that the following configurations also belong to the technical scope of the present disclosure.

(1)

A light deflecting device, including:
a plurality of waveguides that extends in a first direction in parallel to each other and is provided in a semiconductor layer, and is capable of emitting light to an external space of the semiconductor layer and receiving light from the external space; and
an optical system that is provided on a substrate including the semiconductor layer and converts light deflected and emitted from the plurality of waveguides in the first direction into a light beam substantially parallel to a second direction orthogonal to the first direction.
   (2)

The light deflecting device according to (1) above, in which the optical system includes a module lens provided over the plurality of waveguides.

(3)

The light deflecting device according to (2) above, in which the module lens is an annular lens in which a circumferential body is rotated on a rotation axis extending in the second direction.

(4)

The light deflecting device according to (2) above, in which the module lens is a metalens having a planar structure with a period smaller than a wavelength of light emitted from the plurality of waveguides.

(5)

The light deflecting device according to (4) above, in which the metalens has a curvature condensing characteristic.

(6)

The light deflecting device according to (4) above, in which the metalens has a slope condensing characteristic.

(7)

The light deflecting device according to any one of (2) to (6) above, in which the optical system further includes a linear diffraction grating provided between the module lens and the substrate.

(8)

The light deflecting device according to (7) above, in which the linear diffraction grating diffracts light emitted from the plurality of waveguides to a side opposite to a light traveling direction of the plurality of waveguides.

(9)

The light deflecting device according to (1) above, in which the optical system includes an on-chip lens provided for each of the waveguides or for each of the plurality of waveguides, and a module lens provided over the plurality of waveguides.

(10)

The light deflecting device according to (9) above, in which the on-chip lens is a cylindrical lens.

(11)

The light deflecting device according to (9) above, in which the on-chip lens is a metalens having a planar structure with a period smaller than a wavelength of light emitted from the plurality of waveguides.

(12)

The light deflecting device according to (9) above, in which the on-chip lens is a concave lens.

(13)

The light deflecting device according to (9) above, further including a condenser lens that is provided near each of the waveguides and condenses light incident on the waveguide.

(14)

The light deflecting device according to (13) above, in which the condenser lens is a metalens having a planar structure with a period smaller than a wavelength of light incident on the waveguide.

(15)

The light deflecting device according to (13) above, in which the condenser lens is formed by a member having a refractive index higher than a refractive index of a member forming the optical system.

(16)

The light deflecting device according to any one of (9) to (15) above, in which the plurality of waveguides is arranged in the second direction in such a manner as to have a higher density in a central portion than in a peripheral portion.

(17)

The light deflecting device according to (16) above, in which in the peripheral portion, positions of the waveguides and the on-chip lens corresponding to the waveguides are offset in the second direction.

(18)

The light deflecting device according to any one of (1) to (17) above, in which light emitted from the plurality of waveguides is frequency-modulated.

(19)

The light deflecting device according to any one of (1) to (18) above, in which the light emitted from the plurality of waveguides is light belonging to a near infrared region.

(20)

A distance measuring device, including:
a plurality of waveguides that extends in a first direction in parallel to each other and is provided in a semiconductor layer, and is capable of emitting light to an external space of the semiconductor layer and receiving light from the external space; and
an optical system that is provided on a substrate including the semiconductor layer and converts light deflected and emitted from the plurality of waveguides in the first direction into a light beam substantially parallel to a second direction orthogonal to the first direction.

### REFERENCE SIGNS LIST

1 Distance measuring device
2 Object
10 Light source
20 Modulator
30 Optical circulator
40 Optical transmission-reception unit
50 Mixer
60 Detector
70 Processing unit
100 First substrate
110 First semiconductor substrate
111 Optical antenna
112 Heater
113 Diffraction grating
120 First multilayer wiring layer
121, 221 Interlayer insulating film
122, 222 Wiring layer
123, 223 Junction electrode
200 Second substrate
210 Second semiconductor substrate
220 Second multilayer wiring layer
300, 301 Module lens
302 On-chip lens
303 Condenser lens
310 Planarization film

1. A light deflecting device, comprising:
a plurality of waveguides that extends in a first direction in parallel to each other and is provided in a semiconductor layer, and is capable of emitting light to an external space of the semiconductor layer and receiving light from the external space; and
an optical system that is provided on a substrate including the semiconductor layer and converts light deflected and emitted from the plurality of waveguides in the first direction into a light beam substantially parallel to a second direction orthogonal to the first direction.

2. The light deflecting device according to claim 1, wherein the optical system includes a module lens provided over the plurality of waveguides.

3. The light deflecting device according to claim 2, wherein the module lens is an annular lens in which a circumferential body is rotated on a rotation axis extending in the second direction.

4. The light deflecting device according to claim 2, wherein the module lens is a metalens having a planar structure with a period smaller than a wavelength of light emitted from the plurality of waveguides.

5. The light deflecting device according to claim 4, wherein the metalens has a curvature condensing characteristic.

6. The light deflecting device according to claim 4, wherein the metalens has a slope condensing characteristic.

7. The light deflecting device according to claim 2, wherein the optical system further includes a linear diffraction grating provided between the module lens and the substrate.

8. The light deflecting device according to claim 7, wherein the linear diffraction grating diffracts light emitted from the plurality of waveguides to a side opposite to a light traveling direction of the plurality of waveguides.

9. The light deflecting device according to claim 1, wherein the optical system includes an on-chip lens provided for each of the waveguides or for each of the plurality of waveguides, and a module lens provided over the plurality of waveguides.

10. The light deflecting device according to claim 9, wherein the on-chip lens is a cylindrical lens.

11. The light deflecting device according to claim 9, wherein the on-chip lens is a metalens having a planar structure with a period smaller than a wavelength of light emitted from the plurality of waveguides.

12. The light deflecting device according to claim 9, wherein the on-chip lens is a concave lens.

13. The light deflecting device according to claim 9, further comprising a condenser lens that is provided near each of the waveguides and condenses light incident on the waveguide.

14. The light deflecting device according to claim 13, wherein the condenser lens is a metalens having a planar structure with a period smaller than a wavelength of light incident on the waveguide.

15. The light deflecting device according to claim 13, wherein the condenser lens is formed by a member having a refractive index higher than a refractive index of a member forming the optical system.

16. The light deflecting device according to claim 9, wherein the plurality of waveguides is arranged in the second direction in such a manner as to have a higher density in a central portion than in a peripheral portion.

17. The light deflecting device according to claim 16, wherein in the peripheral portion, positions of the waveguides and the on-chip lens corresponding to the waveguides are offset in the second direction.

18. The light deflecting device according to claim 1, wherein light emitted from the plurality of waveguides is frequency-modulated.

19. The light deflecting device according to claim 1, wherein the light emitted from the plurality of waveguides is light belonging to a near infrared region.

20. A distance measuring device, comprising:
a plurality of waveguides that extends in a first direction in parallel to each other and is provided in a semiconductor layer, and is capable of emitting light to an external space of the semiconductor layer and receiving light from the external space; and
an optical system that is provided on a substrate including the semiconductor layer and converts light deflected and emitted from the plurality of waveguides in the first direction into a light beam substantially parallel to a second direction orthogonal to the first direction.
